(19) United States
(12) Patent Application Publication
(10) Pub. No.: US 2010/0304155 A1
(43) Pub. Date: Dec. 2, 2010

(54) FILM DEPOSITION METHOD, FILM DEPOSITION APPARATUS, AND GAS BARRIER FILM

(75) Inventors: TATSUYA FUJINAMI, KANAGAWA (JP); MASATAKA HASEGAWA, KANAGAWA (JP)

Correspondence Address: YOUNG & THOMPSON, 209 Madison Street, Suite 500, Alexandria, VA, 22314, US

(73) Assignee: FUJIFILM CORPORATION, TOKYO (JP)

(21) Appl. No.: 12/789,667

(22) Filed: May 28, 2010

(30) Foreign Application Priority Data
May 29, 2009 (JP) 2009-130678

(51) Int. Cl. C23C 16/505; C23C 16/00; B32B 9/00

(52) U.S. Cl. 428/446; 427/569; 118/718

(57) ABSTRACT

A film deposition method comprises the steps of: transporting on a given transport path a long length of flexible film passed over a surface of a drum that is rotatably provided in a chamber evacuated to a given degree of vacuum; applying a radio-frequency voltage to a film deposition space created between a film deposition electrode and the surface of the drum to generate an electric field in the film deposition space; supplying a feed gas for film deposition into the film deposition space; and limiting an area where the feed gas is supplied so that an area where the electric field is generated in the film deposition space is large enough to cover the area where the feed gas is supplied.

### BACKGROUND OF THE INVENTION

The present invention relates to a roll-to-roll type film deposition method, a roll-to-roll type film deposition apparatus, and a gas barrier film obtained by the film deposition method or the film deposition apparatus, and particularly to a film deposition method and a film deposition apparatus that reduces maintenance labor.

Among film deposition apparatuses for continuously depositing a film on a long length of flexible film (a web of film) by plasma-enhanced CVD technique in a vacuum-filled chamber is one using an electrically grounded drum and an electrode disposed opposite the drum and connected to a radio-frequency power source.

In this type of film deposition apparatus, a flexible film is passed over a given area of the drum, which is then turned to transport the flexible film in a longitudinal direction with the flexible film kept in registration with a given film deposition position as a radio-frequency voltage is applied between the drum and the electrode to generate an electric field while, at the same time, a feed gas, argon gas and the like are introduced between the drum and the electrode to achieve film deposition on the surface of the flexible film by plasma-enhanced CVD. Roll-to-roll type film deposition apparatuses as described above have been proposed in the art.

With a conventional roll-to-roll type film deposition apparatus, a continuous, long-haul film deposition process allows a reaction product to be deposited in the film deposition chamber. The reaction product detaches to become particles, which adversely affect film deposition. Thus, there have been made some propositions to overcome such problems.

The apparatus for manufacturing a thin-film semiconductor described in JP 2002-212744 A comprises in a vacuum tank a flexible film transport means including a supply roll and a take-up roll, a drum roll serving as a grounding electrode and over which a part of the flexible film transported by the transport means is passed, a radio-frequency electrode disposed opposite the drum roll, a gas supply means for supplying reaction gas suitable for the thin-film semiconductor into the vacuum tank, and a gas discharge means for discharging gas by controlling the pressure inside the vacuum tank. The vacuum tank is divided into a reaction chamber containing a part of the drum roll and the radio-frequency electrode and a non-reaction chamber containing the other part of the drum roll and the transport means. A sealing means is provided between the drum roll and the vacuum tank's inner walls at the boundary between the reaction chamber and the non-reaction chamber to limit the flow of the reaction gas.

The non-reaction chamber is also provided with an auxiliary gas supply means for increasing the internal pressure to prevent the reaction gas from flowing into the non-reaction chamber.

The non-reaction chamber is divided into three sections: a drum roll section, a supply roll section, and a take-up roll section. An opening is provided between the supply roll section and the drum roll section and between the take-up roll section and the drum roll section for the flexible film to pass. Each opening is provided with a seal gate means capable of sealing the opening air-tightly.

The radio-frequency electrode is so provided that it can be removed from the vacuum tank, with the reaction chamber and the non-reaction chamber sealed from each other buy a sealing means.

As described above, although the apparatus described in JP 2002-212744 A is configured so that the flow of the reaction gas is limited by a sealing means provided between the reaction chamber and the non-reaction chamber, a reaction product deposits in the reaction chamber. Therefore, maintenance of the apparatus needs to include removal of the reaction product, adding to the time for maintenance.

### SUMMARY OF THE INVENTION

An object of the present invention is to solve the above problems associated with the prior art and provide a film deposition method and a film deposition apparatus that reduce maintenance labor.

Another object of the present invention is to provide a gas barrier film produced by the film deposition method or the film deposition apparatus.

A film deposition method according to the present invention comprises the steps of: transporting on a given transport path a long length of flexible film passed over a surface of a drum that is rotatably provided in a chamber evacuated to a given degree of vacuum; applying a radio-frequency voltage to a film deposition space created between a film deposition electrode and the surface of the drum to generate an electric field in the film deposition space, the film deposition electrode being disposed opposite the surface of the drum through the intermediary of the flexible film passed over the drum with a distance from the surface of the drum; supplying a feed gas for film deposition into the film deposition space; and limiting an area where the feed gas is supplied so that an area where the electric field is generated in the film deposition space is large enough to cover the area where the feed gas is supplied.

A film deposition apparatus according to the present invention comprises: a chamber; an evacuation means for evacuating the chamber to a given degree of vacuum; a rotatable drum disposed in the chamber; a transport means for transporting a long length of flexible film passed over a surface of the drum on a given transport path; a film deposition electrode disposed opposite the surface of the drum through the intermediary of the flexible film passed over the drum with a distance from the surface of the drum so that a film deposition space is created between the surface of the drum and the film deposition electrode; an electric power supply means for applying a radio-frequency voltage between the film deposition electrode and the surface of the drum to generate an electric field in the film deposition space; a feed gas supply means for supplying a feed gas for film deposition into the film deposition space; and a limiting means for limiting an area where the feed gas is supplied by the feed gas supply means so that an area where the electric field is generated in the film deposition space is large enough to cover the area where the feed gas is supplied.

A gas barrier film of the present invention comprises: a flexible film; and a gas barrier film formed on a surface of the flexible film using one of such a film deposition method and such a film deposition apparatus.

### BRIEF DESCRIPTION OF THE DRAWINGS

FIG. 1 is a view schematically illustrating the structure of a film deposition apparatus according to an embodiment of the present invention.

FIGS. 2A and 2B are a front section and a lateral section, respectively, of a film deposition chamber of the film deposition apparatus according to an embodiment of the invention.

FIG. 3 is a view illustrating a relative position of a film deposition electrode plate, limiter members and a drum.

FIG. 4 is a graph illustrating a film thickness distribution as measured in the circumferential direction of the film deposition electrode.

### DETAILED DESCRIPTION OF THE INVENTION

On the following pages, the film deposition method and the film deposition apparatus of the present invention are described in detail with reference to a preferred embodiment illustrated in the accompanying drawings.

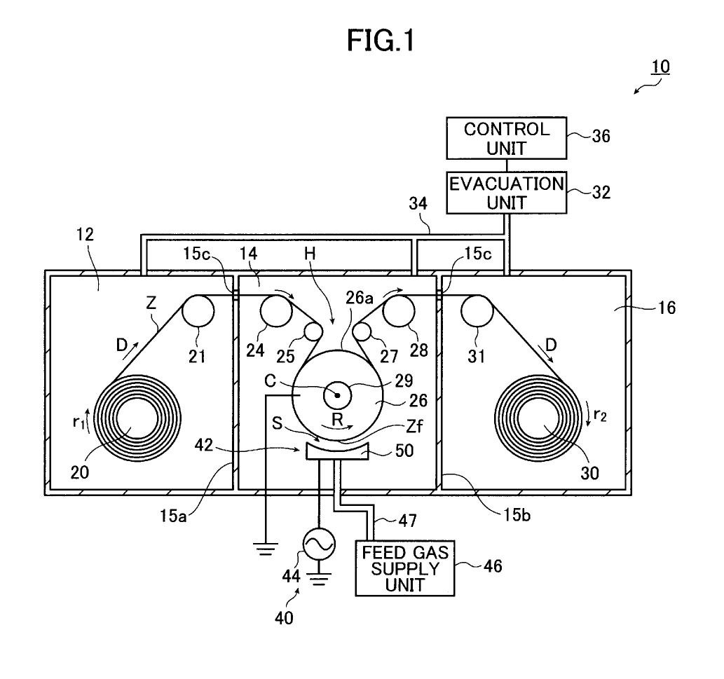

FIG. 1 illustrates the structure of a film deposition apparatus 10 according to an embodiment of the present invention.

The film deposition apparatus 10 is a roll-to-roll type machine that forms a film having a specified function on a surface Zf of a flexible film Z or on the surface of an organic layer, if any, formed on the surface Zf of the flexible film Z. The film deposition apparatus 10 is typically employed to produce functional films such as an optical film or a gas barrier film.

The film deposition apparatus 10 continuously deposits a film on a long length of flexible film Z (a web of film Z) and basically comprises a feed chamber 12 for feeding the flexible film Z, a film deposition chamber 14 for forming a film on the flexible film Z, a take-up chamber 16 for rewinding the flexible film Z having the film formed thereon, an evacuation unit 32, and a control unit 36. The control unit 36 is connected to various rollers and the evacuation unit 32 of the film deposition apparatus 10, etc. to control their operations.

The feed chamber 12 and the film deposition chamber 14 are separated from each other by a wall 15a, and the film deposition chamber 14 and the take-up chamber 16 are separated from each other by a wall 15b; an open slit 15c is formed in the walls 15a and 15b for the flexible film Z to pass through.

The evacuation unit 32 is connected via a duct 34 to the feed chamber 12, the film deposition chamber 14 and the take-up chamber 16. The evacuation unit 32 evacuates the feed chamber 12, the film deposition chamber 14, and the take-up chamber 16 to specified degrees of vacuum.

Each of the feed chamber 12, the film deposition chamber 14, and the take-up chamber 16 is provided with a valve (not shown) for ventilation or adjustment of the amount of evacuation. The control unit 36 controls the valve so that the feed chamber 12, the film deposition chamber 14, and the take-up chamber 16 may be opened to atmosphere.

The evacuation unit 32 evacuates the feed chamber 12, the film deposition chamber 14, and the take-up chamber 16 to maintain them at specified degrees of vacuum and has vacuum pumps such as a dry pump and a turbo-molecular pump. The feed chamber 12, the film deposition chamber 14 and the take-up chamber 16 are each equipped with a pressure sensor (not shown) for measuring their respective internal pressures.

The ultimate degrees of vacuum that should be created by the evacuation unit 32 in the feed chamber 12, the film deposition chamber 14, and the take-up chamber 16 are not particularly limited and may be determined as appropriate in accordance with such factors as the film deposition method used, so that these chambers are maintained at adequate degrees of vacuum. The evacuation unit 32 is controlled by the control unit 36.

The feed chamber 12 supplies the flexible film Z and is provided with a film roll 20 and a guide roller 21.

The film roll 20 has the flexible film Z wound thereon clockwise, for example, and delivers the flexible film Z continuously.

The film roll 20 is typically connected to a drive source such as a motor (not shown). The motor turns the film roll 20 in a direction r₁ to unwind the flexible film Z to continuous supply the flexible film Z.

The guide roller 21 guides the flexible film Z into the film deposition chamber 14 on a specified transport path. The guide roller 21 is formed with a known guide roller.

The guide roller 21 may be a drive roller or a driven roller. The guide roller 21 may also serve as a tension roller for adjusting the tension of the flexible film Z during the transport.

In the film deposition apparatus of the present invention, the flexible film Z is not particularly limited and may be any of various films permitting deposition of a film thereon by a vapor-phase deposition technique. Examples of the flexible film Z include a variety of resin films such as a PET film and a PEN film, as well as various metal sheets such as an aluminum sheet.

The take-up chamber 16 rewinds the flexible film Z having a film formed on its surface Zf in the film deposition chamber 14 as will be described; the take-up chamber 16 comprises a take-up roll 30 and a guide roller 31.

The take-up roll 30 is used to rewind the film-coated flexible film Z into a roll.

The take-up roll 30 is typically connected to a motor (not shown) as a drive source. The motor turns the take-up roll 30 to rewind the flexible film Z after film deposition.

The motor turns the take-up roll 30 in a direction r₂ to rewind the flexible film Z, i.e., clockwise in FIG. 1, to continuously rewind the film-coated flexible film Z.

The guide roller 31 is similar to the guide roller 21 described earlier in that the former guides the flexible film Z delivered from the film deposition chamber 14 to the take-up roll 30 on a specified transport path. The guide roller 31 is formed with a known guide roller. The guide roller 31 may be a drive roller or a driven roller as is the guide roller 21 in the feed chamber 12. The guide roller 31 may also serve as a tension roller.

In the film deposition chamber 14 functioning as a vacuum chamber, a film is continuously formed on the surface Zf of the flexible film Z by a vapor-phase film deposition technique, typically by plasma-enhanced CVD, as the flexible film Z is transported.

The film deposition chamber 14 is constructed by using a material which is commonly employed to form a variety of vacuum chambers, such as stainless steel, aluminum, and an aluminum alloy.

The film deposition chamber 14 is provided with four guide rollers 24, 25, 27, and 28, as well as a drum 26 and a film deposition unit 40.

The guide roller 24, the guide roller 25, the drum 26, the guide roller 27, and the guide roller 28 are positioned in this order down the stream in the transport direction.

The guide rollers 24 and 28 are disposed opposite and parallel to each other with a given distance between them. The guide rollers 24 and 28 are disposed so that their axes of rotation are normal to the transport direction D of the flexible film Z.

The guide rollers 25 and 27 are disposed opposite and parallel to each other with a distance between them that is smaller than that separating the guide rollers 24 and 28. The guide rollers 25 and 27 are disposed so that their axes of rotation are normal to the transport direction D of the flexible film Z.

The guide roller 24 transports the flexible film Z delivered from the guide roller 21 in the feed chamber 12 to the drum 26. The guide rollers 24 and 25 typically turn about an axis of rotation normal to the transport direction D of the flexible film Z (the direction being referred to below as the axial direction), and their length in the axial direction is greater than the length of the flexible film Z in the width direction normal to its longitudinal direction (the latter length being referred to below as the width of the flexible film Z).

The film roll 20, and the guide rollers 21, 24, and 25 combine to constitute a first transport means according to the present invention.

The guide rollers 27 and 28 transport the flexible film Z passed over the drum 26 to a guide roller 31 provided in the take-up chamber 16. The guide rollers 27 and 28 turn about an axis of rotation extending in the axial direction and their length in the axial direction is greater than the width of the flexible film Z.

The guide rollers 27, 28, 31, and the take-up roll 30 combine to constitute a second transport means according to the present invention.

Except for the features described above, the guide rollers 24, 25, 27 and 28 have the same configuration as the guide roller 21 provided in the feed chamber 12 and are therefore not described in detail.

The drum 26 is provided below a space H between the guide rollers 24, 25 and 27, 28. The drum 26 is so positioned that its axis is parallel to those of the guide rollers 24, 25, 27, and 28.

The drum 26 typically has a cylindrical shape and has a cylindrical support member (not shown) provided on both end faces thereof. The support members are rotatably supported by, for example, bearings (not shown) attached to wall surfaces of the film deposition chamber 14. Thus, the drum 26 turns about an axis of rotation C in a direction of rotation R.

As the drum 26 turns with the flexible film Z passed over the peripheral surface 26a of the drum 26, the flexible film Z passes a given film deposition position and travels onward in the transport direction D.

The length of the drum 26 in an axial direction Y (longitudinal direction) is greater than the width of the flexible film Z. The drum 26 is electrically grounded.

As illustrated in FIG. 1, the film deposition unit 40 is provided below the drum 26. When the drum 26 turns with the flexible film Z passed over it, a film is formed on the surface Zf of the substrate Z as it is transported in the transport direction D.

The film deposition unit 40 forms a film typically by capacitively coupled plasma enhanced CVD (CCP-CVD). The film deposition unit 40 comprises a film deposition electrode 42, a radio-frequency power source 44, and a feed gas supply unit 46. Although not shown, the radio-frequency power source 44 and the material gas supply unit 46 of the film deposition unit 40 are connected to the control unit 36. The control unit 36 controls the radio-frequency power source 44 and the feed gas supply unit 46 in the film deposition unit 40.

The film deposition electrode 42 is separated by a given distance from the surface 26a of the drum 26 to form a gap S between them in a lower part of the film deposition chamber 14.

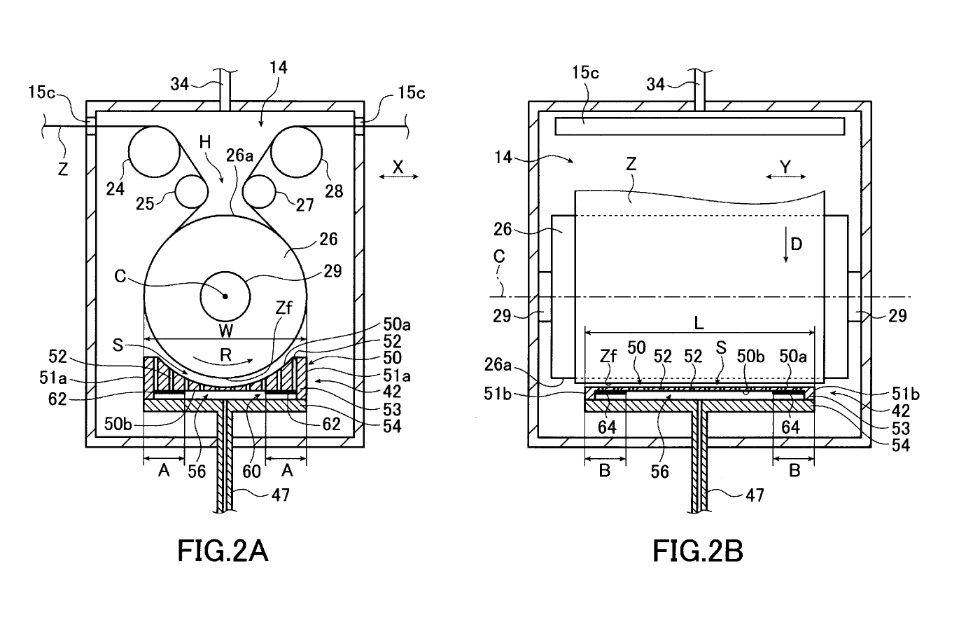

As illustrated in FIG. 2A, the film deposition electrode 42 comprises a film deposition electrode plate 50 and a holder 54 that holds the film deposition electrode plate 50.

The film deposition electrode plate 50 has a surface 50a facing the drum 26 that is curved so as to contour the surface 26a of the drum 26. The film deposition electrode plate 50 is formed such that

the distance between its surface 50a and the surface 26a of the drum 26 remains a given distance on any line normal to the surface 50a and passing through the axis of rotation C of the drum 26.

The film deposition electrode plate 50 is disposed so that its surface 50a may be on a circle that is concentric with the drum 26 having the surface 26a.

As illustrated in FIG. 1, the film deposition electrode 42 (film deposition electrode plate 50) is connected to the radio-frequency power source 44, which applies a radio-frequency voltage to the film deposition electrode plate 50 of the film deposition electrode 42. Thus, a given range of electric field is generated in the gap S between the film deposition electrode 42 (film deposition electrode plate 50) and the drum 26.

The radio-frequency power source 44 is capable of adjusting the radio-frequency power (RF power) to be applied.

The film deposition electrode 42 and the radio-frequency power source 44 may optionally be connected to each other via a matching box for impedance matching.

The film deposition electrode 42 is of a type generally called “a shower head electrode” and has a cavity 56 inside; the film deposition electrode plate 50 has a plurality of through-holes 52 formed at constant intervals in its surface 60a. The film deposition electrode 42 permits uniform supply of the feed gas into the gap S.

The holder 54 supports the film deposition electrode plate 50; the two members can be detached from each other.

The film deposition electrode 54 is connected to the material gas supply unit 46 through a supply pipe 47. The cavity 56 of the holder 54 communicates with the plurality of through-holes formed in the surface 50a of the film deposition electrode plate 50. As will be described later, the feed gas supplied from the feed gas supply unit 46 flows through the pipe 47, the cavity 56, and the plurality of through-holes 52 of the film deposition electrode plate 50 to be released from the surface 50a of the film deposition electrode plate 50, and the feed gas evenly supplied in the gap S.

The film deposition electrode 42 achieves film deposition over a length L in the axial direction Y of the drum 26 on the surface Zf of the flexible film Z as illustrated in FIG. 2B. Thus, the range L is the film deposition range in the axial direction Y.

In the circumferential direction X normal to the axial direction Y of the drum 26, film deposition is achieved on the surface Zf of the flexible film Z over a length W in FIG. 2A. Thus, the length W is the film deposition range in the axial direction Y.

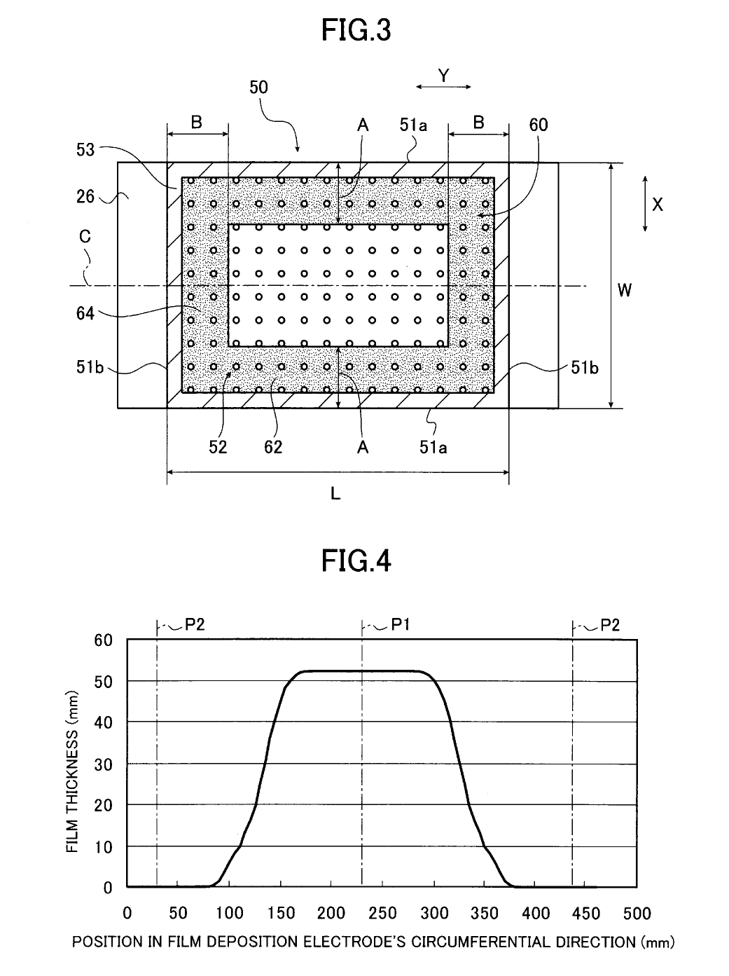

The film deposition electrode 42 is provided with a limiter 60 for closing some of the through-holes 52 of the film deposition electrode plate 50 to limit ejection of the feed gas from the closed through-holes 52. The limiter 60 is provided in the cavity 56 of the film deposition electrode 42 to close some of the through-holes 52 on a rear side 50b of the film deposition electrode plate 50. The limiter 60 may typically be attached to the rear side 50b of the film deposition electrode plate 50 with the holder 54 detached from the film deposition electrode plate 50. As illustrated in FIG. 3, the limiter 60 has an annular configuration formed by a pair of first limiter members 62 disposed opposite each other and extending in the axial direction Y of the drum 26 and a pair of second limiter members 64 disposed opposite each other and extending in the circumferential direction X of the drum 26.

According to the embodiment, the limiter 60 closes some of the through-holes 52 so that the area of the electric field generated in the gap S by the radio-frequency power source 44 is larger than the area of the gap S where a sufficient amount of reaction gas for film deposition is supplied from the film deposition electrode plate 50. Thus, the reaction gas is depleted near the ends of the film deposition electrode plate 50, which reduces the amount of reaction gas to disperse from the gap S in the film deposition chamber 14.

The state that the area of generated electric field is larger than the area where a sufficient amount of reaction gas for film deposition is supplied denotes a state, for example, that the film deposition rate achieved at a position located 25 mm inwardly from each end 51a of the film deposition electrode plate 50 in the circumferential direction X is not greater than 30% of the film deposition rate achieved at the center of the film deposition unit plate 50.

According to the embodiment, the limiter 60 limits the film deposition rate achieved at a position located 25 mm inwardly from the ends 51a and 51b of the film deposition electrode plate 50 is not greater than 30% of the film deposition rate achieved at the center of the film deposition unit plate 50. The range of area where the feed gas supplied to the film deposition electrode 42 disperses varies with such film deposition conditions as the kind of feed gas and the supply rate thereof. Therefore, the width of the first limiter members 62 and the width of the second limiter members 64 should be previously determined by experiments or other means to ensure the film deposition rate of not greater than 30% of that attained at the center under each film deposition condition.

Thus, the dimensions of the area covered by the limiter 60 need to be changed according to the film deposition condition. Therefore, the limiter 60 is preferably provided with a mechanism permitting adjustment of the area where the through-holes 52 are closed by changing the widths of the first limiter members 62 and the second limiter members 64 of the limiter 60.

FIG. 3 shows a positional relationship between the film deposition electrode plate, the limiter, and the drum.

The area where the through-holes 52 are closed by the limiter 60 is the area covered by the first and the second limiter members 62, 64 each having widths A, B minus a thickness 53 of the film deposition electrode plate 50, respectively.

The limiter 60 closes the through-holes 52 in an area measuring, say, 50 mm in both directions X and Y.

According to the embodiment, the limiter 60 need only close some of the through-holes 52 so that at least in the circumferential direction X, the film deposition rate achieved at a position located 25 mm inwardly from the end 51a of the film deposition electrode plate 50 is not greater than 30% of the film deposition rate achieved at the center of the film deposition unit plate 50. Thus, the limiter 60 need only have at least the first limiter members 62.

Where the drum 26 and the film deposition electrode plate 50 are each equipped with a heater (not shown) and a temperature sensor for measuring the temperature (also not shown), the drum 26 and the film deposition electrode plate 60 can be adjusted to the same temperature.

The material gas supply unit 46 is typically connected to the cavity 56 of the support member 54 through the supply pipe 47. The feed gas supply unit 46 uniformly supplies the film-forming feed gas into the gap S through the through-holes 52 formed in the surface 50a of the film deposition electrode plate 50 of the film deposition electrode 42. The gap S between the surface 26a of the drum 26 and the film deposition electrode 42 serves as a space where plasma is generated, hence, as a film deposition space.

Where an SiO₂ film is to be formed, a TEOS gas is used with oxygen gas, which is employed as an active species gas. If a silicon nitride film is to be formed, SiH₄ gas, NH₃ gas and N₂ gas (dilution gas) are used. In this embodiment, a feed gas containing an active species gas and a dilution gas is simply referred to as a feed gas.

The material gas supply unit 46 may be chosen from a variety of gas introducing means that are employed in CVD apparatuses.

The feed gas supply unit 46 may supply the gap S with not only the feed gas but an inert gas such as argon or nitrogen gas, an active species gas such as oxygen gas, and various other gases that are used in CVD. As described above, where more than one kind of gas is introduced, the gases may be mixed together in the same pipe and passed through the through-holes of the film deposition electrode 42 into the gap S; alternatively, the gases may be supplied through different pipes and passed through the through-holes of the film deposition electrode 42 into the gap S.

The types of the material gases, the inert gas and the active species gas, as well as the amounts in which they are introduced may be chosen and set as appropriate according to such conditions as the type of the film to be formed and the desired film deposition rate.

Note that the radio-frequency power source 44 may be of any known type that is employed in film deposition by plasma-enhanced CVD. The maximum power output and other characteristics of the radio-frequency power source 44 are not particularly limited and may be chosen and set as appropriate according to such conditions as the type of the film to be formed and the desired film deposition rate.

The film deposition electrode 50 is curved to contour the surface 26a of the drum 26 according to the embodiment but may have any other configuration as appropriate that permits film deposition using a CVD technique including one formed by bending a member that is rectangular in planar view, or one formed by disposing a plurality of flat electrodes, each rectangular in planar view, so as to contour the surface 26a of the drum 26 along the direction of rotation R. In the latter case, electrical conduction is established between the individual electrode plates, which are arranged such that the surface of each electrode plate is at a predetermined distance from the surface 26a of the drum 26 on a line that is normal to the surface of each electrode plate and which passes through the axis of rotation C of the drum 26.

In the embodiment, the film deposition electrode 42 has such a configuration that through-holes are formed in the surface 50a of the film deposition electrode plate 50. However, other configurations are possible, provided that they are capable of uniformly supplying the feed gas into the gap S, the film deposition space; For example, open slits may be formed in the bent portions of the film deposition electrode 50 such that the material gas is released through the open slits.

Now, we describe the operation of the film deposition apparatus 10 according to the embodiment.

In the film deposition apparatus 10, a long length of flexible film Z is transported along the predetermined path starting from the feed chamber 12 and ending in the take-up chamber 16 through the film deposition chamber 14 where a film is formed on the surface Zf of the flexible film Z to obtain a gas barrier film or another product.

According to the embodiment, an electric field is generated over a range larger than that where the reaction gas is supplied in an amount sufficient for film deposition. Specifically, the limiter 60 adjusts the film deposition rate attained at a position located 25 mm inwardly from the end 51a of the film deposition electrode plate 50 is not larger than 30% of the film deposition rate attained at the center of the film deposition electrode plate 50.

The flexible film Z, wound in the film roll 20, is transported through the guide roll 21 into the film deposition chamber 14. In the film deposition chamber 14, the flexible film Z follows the path through the guide rollers 24, 25, the drum 26, and the guide rollers 27, 28 to reach the take-up chamber 16. In the take-up chamber 16, the flexible film Z passes the guide roller 31 before it is rewound by the take-up roll 30. After leading the flexible film Z along this transport path, the radio-frequency power source 44 applies a radio-frequency voltage to the film deposition electrode 42 in the film deposition unit 40, while, at the same time, the feed gas supply unit 46 supplies the feed gas to the film deposition electrode 42 through the pipe 47, with the interiors of the feed chamber 12, the film deposition chamber 14, and the take-up chamber 16 kept at a specified degree of vacuum by the evacuation unit 32.

No feed gas is ejected through the through-holes 52 located close to the ends 51a, 51b of the film deposition electrode plate 50 where the film deposition electrode 42 is provided with the limiter 60. The feed gas ejected through the through-holes 52 is depleted in an area of the film deposition electrode plate 50 located a given distance inwardly from the ends 51a, 51b thereof. The feed gas is evenly supplied to the gap S from the other area of the film deposition electrode plate 50.

When electromagnetic waves are radiated around the film deposition electrode 42, plasma localized near the film deposition electrode 42 is generated in the gap S, whereupon the feed gas is excited and dissociated to yield a reaction product, so that the reaction product deposits to form a film. Because the feed gas is depleted in an area of the film deposition electrode plate 50 close to the ends 51a, 51b, generation of the reaction product is limited in an area of the film deposition electrode plate 50 close to the ends 51a, 51b. Therefore, film deposition takes place at a rate of only 30% or less per unit time at the position located 25 mm inwardly from the ends 51a, 51b of the film deposition electrode plate 50 than in the area at the center of the film deposition electrode plate 50. Under such conditions, a film is formed to a given thickness on the surface Zf of the flexible film Z as it is fed at a given speed.

According to the embodiment, because the reaction product is generated only in a limited area in the film deposition process, the amount of the reaction product dispersing from the gap S (film deposition zone) into the film deposition chamber 14 can be reduced. This limits the dispersion of the reaction product in the film deposition chamber 14. This reduces the chances that the reaction product might attach to the surface Zf of the flexible film Z other than in the gap S (film deposition zone) and that the flexible film Z might entrain the reaction product and thus adversely affect the quality of the film formed. Thus, the film produced can have a good quality, and the gas barrier film finally obtained can have excellent gas barrier properties.

The film roll 20 is turned clockwise by a motor to continuously feed the flexible film Z, which is held onto the drum 26 in a position where plasma is generated as the drum 26 is turned at a given speed to allow a film to be continuously formed with a given thickness on the surface Zf of the flexible film Z by the film deposition unit 40, such that the formed film has a uniform thickness and a small thickness distribution particularly in the direction of width of the flexible film Z. The flexible film Z having a specified film formed on the surface Zf is transported through the guide rollers 28 and 31, and rewound by the take-up roll 30 to produce a functional film such as a gas barrier film.

Thus, a functional film can be formed by continuously producing on a long length of flexible film Z a film that has a uniform thickness and a small thickness distribution particularly in the direction of width of the flexible film Z and has a given thickness.

Further, the embodiment is capable of limiting the area where the reaction product is generated and limiting the dispersion thereof in the film deposition chamber 14. This minimizes the contamination of the film deposition chamber 14 in the film deposition process. This limits the region in the film deposition chamber 14 that requires removal of the reaction product that deposited and hence reduces the amount of the reaction product to be removed, resulting in a simplified maintenance operation.

In the foregoing embodiment of the present invention, the film to be deposited is not particularly limited; any film as appropriate may be formed according to the function that is required of the functional film finally to be produced, provided that the film can be deposited by a CVD technique. The thickness of the film to be deposited also is not particularly limited, and the required thickness may be determined as appropriate according to the performance required of the functional film to be produced.

Further, the film to be deposited need not be limited to have a single-layer structure, but may have a multiple-layer structure. Where a film having a multiple-layer structure is to be formed, the individual layers may be the same or different from each other.

Where the functional film to be produced is, for example, a gas barrier film (water vapor barrier film), an inorganic film such as a silicon nitride film, an aluminum oxide film, or a silicon oxide film is deposited on the flexible film Z.

Where the functional film to be produced is a protective film for a variety of devices or apparatuses including display devices such as organic EL displays and liquid-crystal displays, an inorganic film such as a silicon oxide film is deposited on the flexible film Z.

Further, where the functional film to be produced is an optical film such as an anti-light reflective film, a light reflective film, and any of various filters, a film having the desired optical characteristics or a film formed of materials that exhibit desired optical characteristics is deposited.

The functional film thus produced by the film depositing apparatus 10 according to the foregoing embodiment of the present invention is characterized in that the layer formed on the flexible film Z has a uniform thickness, particularly in the direction of width of the flexible film Z. Thus, where the functional film is a gas barrier film, it offers good gas barrier properties.

While the film deposition method, the film deposition apparatus, and the gas barrier film obtained by the film deposition method or the film deposition apparatus according to the present invention have been described above in detail, the present invention is by no means limited to the foregoing embodiments, and various improvements and modifications may of course be made without departing from the scope and spirit of the invention.

### EXAMPLES

The present invention is described below in further detail with reference to specific examples of the invention.

The film deposition apparatus 10 illustrated in FIG. 1 was used for the examples described below. The dimensions of the first limiter members 62 and the second limiter members 64 were set to various values given in Table 1 below to form a silicon nitride film on the surface of a flexible film under conditions described below. The film deposition time is given in Table 1.

The flexible film used was a polyethylene terephthalate film (“Cosmo-Shine A4300,” a PET film provided by Toyobo Co., Ltd.).

All the Examples 1 to 5 shown in Table 1 used SiH₄ gas (silane gas), NH₃ gas (ammonia gas) and N₂ gas (nitrogen gas). The flow rate of SiH₄ gas (silane gas) was 125 sccm; the flow rate of NH₃ gas (ammonia gas) was 125 sccm; the flow rate of N₂ gas (nitrogen gas) was 800 sccm; the applied radio-frequency power was 2500 W; and the film deposition pressure was 100 Pa.

In Example 1, a silicon nitride film was deposited with the drum kept stationary to obtain a film thickness distribution illustrated in FIG. 4.

In Examples 2 to 6, a silicon nitride film was deposited with the drum in rotation for respective film deposition times given in Table 1 to produce gas barrier films having a silicon nitride film deposited on the flexible film.

The gas barrier films produced in Examples 2 to 6 were rated for gas barrier properties.

The gas barrier properties were rated using WVTR (moisture vapor transmission rate). WVTR (water vapor transmission rate) measurement was conducted using a water vapor transmission rate tester AQUATRAN (trademark) provided by MOCON.

In Examples 2 to 6, the film deposition chamber was opened after the film deposition times given in Table 1 elapsed to visually observe the reaction product that deposited in the film deposition chamber and provide ratings of “excellent”, “very good”, “good”, “fair” and “poor” as shown in Table 1.

The ratings of “excellent”, “very good”, “good”, “fair”, and “poor” were given respectively for observations as follows. The rating of “excellent” was given when no reaction product was observed other than in the film deposition zone. The rating of “very good” was given when a small amount of deposit of reaction product was observed other than in the film deposition zone. The rating of “good” was given when a deposit of reaction product was observed other than in the film deposition zone but detachment of the deposit was not observed. The rating of “fair” was given when a great amount of deposit of reaction product was observed other than in the film deposition zone and the deposit was slightly detached. The rating of “poor” was given when a great amount of deposit of reaction product was observed other than in the film deposition zone and a great amount of the deposit was detached.

TABLE 1

| | | | Film | | Film |
|---|---|---|---|---|---|
| | A | B | deposition | WVTR | deposition |
| | (mm) | (mm) | time (min) | (g/m²/day) | chamber |
| Example 1 | 175 | 0 | 1 | — | — |
| Example 2 | 120 | 120 | 60 | 0.003 | Excellent |
| Example 3 | 120 | 0 | 60 | 0.005 | Very good |
| Example 4 | 50 | 50 | 60 | 0.009 | Good |
| Example 5 | 50 | 0 | 60 | 0.012 | Fair |
| Example 6 | 0 | 0 | 60 | 0.2 | Poor |

In Example 1, the ejection of the feed gas through the through-holes was limited only in the film deposition electrode's circumferential direction. FIG. 4 shows the film thickness distribution obtained in Example 1. Comparing the film thickness at the center P1 and that at the point P2 located 25 mm inwardly from each end of the film deposition electrode in the circumferential direction thereof (drum's circumferential direction) as indicated in FIG. 4, the film thickness at the Position P2 is almost zero, indicating that no film deposition took place near the ends of the film deposition electrode, and thus is not greater than 30% of the film thickness at the center P1. Thus, the limiter can adjust the film thickness at the point P2.

In Example 2, the ejection of the feed gas through the through-holes was limited in both the circumferential direction X (see FIG. 2A) and the axial direction Y (see FIG. 2B). In Example 2, the point P2 where a range of 30% or less was yielded is located 78 mm from each end.

In Example 3, the ejection of the feed gas through the through-holes was limited in the circumferential direction X (see FIG. 2A). In Example 3, the point P2 where a range of 30% or less was yielded is located 78 mm from each end.

In Example 4, the ejection of the feed gas through the through-holes was limited in both the circumferential direction X (see FIG. 2A) and the axial direction Y (see FIG. 2B). In Example 4, the point P2 where a range of 30% or less was yielded is located 32 mm from each end.

In Example 5, the ejection of the feed gas through the through-holes was limited in the circumferential direction X (see FIG. 2A). In Example 5, the point P2 where a range of 30% or less was yielded is located 32 mm from each end.

In Example 6, no limiter was provided. Therefore, the film thickness was the same over the whole area of the film deposition electrode.

All Examples 2 to 5 yielded films having a small WVTR moisture vapor transmission rate and excellent gas barrier properties. Furthermore, the reaction products were deposited only in small amounts in the film deposition chamber.

Example 6, on the other hand, yielded a film having a great WVTR (moisture vapor transmission rate) and gas barrier properties that are inferior to those of the films obtained in Examples 2 to 5, and allowed a great amount of reaction product to deposit in the film deposition chamber.

Thus, the area where a reaction product deposits can be limited by closing the through-holes of the film deposition electrode through which the feed gas is ejected to deplete the supply of feed gas near the ends of the film deposition electrode. This limited the amount of reaction product that could disperse in the film deposition chamber and thus increased ease of maintenance. Further, the gas barrier film obtained has high gas barrier capabilities.

What is claimed is:

1. A film deposition method comprising the steps of:
transporting on a given transport path a long length of flexible film passed over a surface of a drum that is rotatably provided in a chamber evacuated to a given degree of vacuum;
applying a radio-frequency voltage to a film deposition space created between a film deposition electrode and the surface of the drum to generate an electric field in the film deposition space, the film deposition electrode being disposed opposite the surface of the drum through the intermediary of the flexible film passed over the drum with a distance from the surface of the drum;
supplying a feed gas for film deposition into the film deposition space; and
limiting an area where the feed gas is supplied so that an area where the electric field is generated in the film deposition space is large enough to cover the area where the feed gas is supplied.

2. The film deposition method according to claim 1,
wherein the film deposition electrode is a shower head electrode having through-holes for ejecting the feed gas,
the area where the feed gas is supplied being limited by closing at least those of the through-holes of the shower head electrode that are positioned in a range located within a first distance from each end of the shower head electrode in a circumferential direction of the drum.

3. The film deposition method according to claim 2, wherein the area where the feed gas is supplied is limited by closing also those of the through-holes of the shower head electrode that are positioned in a range located within a second distance from each end of the shower head electrode in an axial direction of the drum.

4. The film deposition method according to claim 1, wherein a film deposition rate at a point located 25 mm inwardly from edges of the film deposition electrode is not greater than 30% of a film deposition rate at a center of the film deposition electrode.

5. A film deposition apparatus comprising:
a chamber;
an evacuation means for evacuating the chamber to a given degree of vacuum;
a rotatable drum disposed in the chamber;
a transport means for transporting a long length of flexible film passed over a surface of the drum on a given transport path;
a film deposition electrode disposed opposite the surface of the drum through the intermediary of the flexible film passed over the drum with a distance from the surface of the drum so that a film deposition space is created between the surface of the drum and the film deposition electrode;
an electric power supply means for applying a radio-frequency voltage between the film deposition electrode and the surface of the drum to generate an electric field in the film deposition space;
a feed gas supply means for supplying a feed gas for film deposition into the film deposition space; and
a limiting means for limiting an area where the feed gas is supplied by the feed gas supply means so that an area where the electric field is generated in the film deposition space is large enough to cover the area where the feed gas is supplied.

6. The film deposition apparatus according to claim 5,
wherein the film deposition electrode is a shower head electrode having through-holes for ejecting the feed gas,
the limiting means comprising limiter members for closing those of the through-holes of the shower head electrode that are positioned in ranges located within a first distance from each end of the shower head electrode at least in a circumferential direction of the drum.

7. The film deposition apparatus according to claim 6, wherein the limiter members close also those of the through-holes of the shower head electrode that are positioned in ranges located within a second distance from each end of the shower head electrode in an axial direction of the drum.

8. The film deposition apparatus according to claim 6,
wherein the film deposition electrode comprises a first surface facing the drum and a second surface opposite from the first surface,
the limiter members being attached to the second surface of the film deposition electrode.

9. The film deposition apparatus according to claim 6, wherein the ranges where the through-holes are closed are adjustable by the limiter members.

10. A gas barrier film comprising:
a flexible film; and
a gas barrier film formed on a surface of the flexible film using the film deposition method according to claim 1.

11. A gas barrier film comprising:
a flexible film; and
a gas barrier film formed on a surface of the flexible film using the film deposition apparatus according to claim 5.
